(19) United States
(12) Patent Application Publication
(10) Pub. No.: US 2014/0112483 A1
(43) Pub. Date: Apr. 24, 2014

(54) DISTANCE-BASED AUTOMATIC GAIN CONTROL AND PROXIMITY-EFFECT COMPENSATION

(71) Applicant: Walter Etter, Wayside, NJ (US)

(72) Inventor: Walter Etter, Wayside, NJ (US)

(73) Assignee: ALCATEL-LUCENT USA INC., Murray Hill, NJ (US)

(21) Appl. No.: 13/659,602

(22) Filed: Oct. 24, 2012

(51) Int. Cl. H03G 3/20

(52) U.S. Cl. CPC H03G 3/20
USPC 381/56; 381/107; 381/98; 381/102

(57) ABSTRACT

An automatic gain control derives the gain from the distance between the sound source and the microphone. The distance-based automatic gain control normalizes signal level changes caused by a speaker not maintaining a constant distance with respect to the microphone. Also, a proximity-effect compensation that derives the adaptive filter from the distance between the sound source and the microphone. The proximity-effect compensation corrects frequency response changes due to undesired proximity-effect variations. Determination of the distance between a sound source and a microphone permits accurate compensation for both frequency response changes and distance-related signal level changes.

### FIELD OF INVENTION

The invention is related to audio signal processing.

### BACKGROUND

When a speaker speaks into a microphone, the microphone output signal level changes with the distance between the microphone and the speaker. Often, speakers do not maintain a fixed distance to a microphone, thereby producing undesirable changes in the microphone output signal level. Also, if the microphone used is a so called pressure-gradient microphone, changes in the distance between the microphone and the speaker can lead to an additional effect known as proximity effect, which is characterized by spectral changes (or more specifically, bass response variations) in the microphone output signal in addition to changes in the microphone output signal level.

### SUMMARY

In one embodiment, an automatic gain control system comprises a gain controller configured to receive an input audio signal and configured to generate an output audio signal; wherein the gain controller is configured to control a level of the output audio signal based on a distance between a sound source and a microphone.

In some embodiments of the above automatic gain control system, the gain controller comprises a gain control module, which is configured to generate a gain control signal based on a desired gain for controlling the level of the output audio signal, the desired gain being determined based on an inversely proportional relationship between the sound pressure level at the microphone and the distance between the microphone and the sound source.

In some embodiments of any of the above automatic gain control systems, the gain controller further comprises a variable gain amplifier that is configured to receive the gain control signal generated by the gain control module and is further configured to control a gain of the variable gain amplifier based on gain control signal.

In some embodiments of any of the above automatic gain control systems, the gain control module comprises a digital signal processor or an application specific integrated circuit that is adapted to perform computations to determine the desired gain for controlling the level of the output audio signal.

Some embodiments of any of the above automatic gain control systems further comprise a distance sensor adapted to determine the distance between the sound source and the microphone.

In some embodiments of any of the above automatic gain control systems, the distance between a sound source and a microphone accounts for a dimension of the sound source.

In some embodiments of any of the above automatic gain control systems, the relationship between the sound pressure level at the microphone and the distance between the microphone and the sound source is an inversely proportional relationship based on direct sound field model or a first order filter relationship based on a combined direct and diffuse sound field model.

In one embodiment, a frequency control system comprises a frequency response controller configured to receive an input audio signal and configured to generate an output audio signal; wherein the frequency response controller is configured to control the frequency spectrum of the output audio signal based on a distance between a sound source and a microphone.

In some embodiments of the above frequency control system, the frequency response controller comprises a proximity-effect compensation module, which is configured to generate a filter control signal based on a desired frequency spectrum of the output audio signal, which is determined based on the distance between the sound source and the microphone.

In some embodiments of any of the above frequency control systems, the filter control signal is also determined based on an angle of incidence of the sound with respect to the microphone.

In some embodiments of any of the above frequency control systems, the frequency response controller further comprises an adaptive filter that is configured to receive the filter control signal generated by the proximity-effect compensation module and is further configured to control a filter of the adaptive filter based on the filter control signal.

In some embodiments of any of the above frequency control systems, the proximity-effect compensation module comprises a digital signal processor or an application specific integrated circuit that is adapted to perform computations to determine the desired frequency spectrum of the output audio signal based on the distance between the sound source and the microphone and generate the filter control signal.

Some embodiments of any of the above frequency control systems further comprise a distance sensor adapted to determine the distance between the sound source and the microphone, and/or an orientation sensor adapted to determine the angle of incidence of the sound with respect to the microphone.

In some embodiments of any of the above frequency control systems, the distance between a sound source and a microphone accounts for a dimension of the sound source.

In one embodiment, an audio signal processing system comprises a frequency response controller configured to receive an input audio signal and configured to generate an output audio signal, wherein the frequency response controller is configured to control the frequency spectrum of the output audio signal based on a distance between a sound source and the microphone; and a gain controller configured to control the level of the output audio signal based on the distance between the sound source and the microphone.

In some embodiments of the above audio signal processing system, the gain controller comprises a gain control module, which is configured to generate a gain control signal based on a desired gain for controlling the level of the output audio signal, the desired gain being determined based on a relationship between the sound pressure level at the microphone and the distance between the microphone and the sound source.

In some embodiments of any of the above audio signal processing systems, the gain controller further comprises a variable gain amplifier that is configured to receive the gain control signal generated by the gain control module and is further configured to control a gain of the variable gain amplifier based on the gain control signal. It is to be understood that the gain when expressed on a logarithmic scale, such as dB), can be positive (i.e., amplification) or negative (i.e., attenuation); or alternatively, on a linear scale, the gain can be greater than 1 (i.e., amplification) or lesser than 1 (i.e., attenuation).

Some embodiments of any of the above audio signal processing systems further comprise a distance sensor adapted to determine the distance between the sound source and the microphone.

In some embodiments of any of the above audio signal processing systems, the frequency response controller comprises a proximity-effect compensation module, which is configured to generate a filter control signal based on a desired frequency spectrum of the output audio signal; and an adaptive filter that is configured to receive the filter control signal generated by the proximity-effect compensation module and is further configured to control a filter of the adaptive filter based on the filter control signal.

In some embodiments of any of the above audio signal processing systems, the distance between a sound source and a microphone accounts for a dimension of the sound source.

### BRIEF DESCRIPTION OF THE DRAWINGS

The foregoing summary, as well as the following detailed description of the embodiments, is better understood when read in conjunction with the appended drawings. For the purpose of illustrating the invention, various embodiments are shown in the drawings, it being understood, however, that the invention is not limited to the specific embodiments disclosed. In the drawings:

FIG. 1 shows an exemplary illustration of an audio signal processing system 1;

FIG. 2 shows an exemplary illustration of an audio signal processing system 1 configured to provide automatic gain control;

FIG. 3 shows an exemplary illustration of an audio signal processing system 1 configured to provide continuous proximity-effect compensation;

FIG. 4 shows an exemplary illustration of an audio signal processing system 1 configured to provide automatic gain control and continuous proximity-effect compensation;

FIG. 5 shows Graph 1 illustrating a sound pressure ration;

FIG. 6 shows Graph 2a illustrating a desired gain;

FIG. 7 shows Graph 2b illustrating a desired gain with critical distance as a parameter;

FIG. 8 shows Graph 3 illustrating the magnitude frequency response of the proximity effect;

FIG. 9 shows Graph 4 illustrating the proximity effect for various pressure-gradient microphones at fixed speaker-to-microphone distances;

FIG. 10 shows Graph 5 illustrating the proximity effect for various sound arrival angles at fixed speaker-to-microphone distance and fixed directivity;

FIG. 11 shows Graph 6 illustrating sound pressure levels plotted against a radius with and without source-size compensation;

FIG. 12 shows Graph 7 illustrating recorded speech signals (a), (b); output of distance-based automatic gain control (c)-(e); and output of conventional signal-based automatic gain control (f); and

FIG. 13 shows Graph 8 illustrating gain of distance-based automatic gain control, corner frequency of proximity-effect compensation filter, and gain of conventional signal-based automatic gain control.

### DETAILED DESCRIPTION

Before the various embodiments are described in further detail, it is to be understood that the invention is not limited to the particular embodiments described. It is also to be understood that the terminology used is for the purpose of describing particular embodiments only, and is not intended to limit the scope of the claims of the present application.

The present application provides automatic gain control that derives the gain from the sound source to microphone distance. The concept makes use of the fact that microphone output levels vary inversely with the distance to a spherical sound source. In particular, distance-based automatic gain control can normalize distance-based signal level changes without deteriorating signal quality. Distance-based automatic gain control is applicable to situations in which a speaker does not maintain a constant microphone distance. Additionally, the present application provides proximity-effect Compensation of undesired bass response variations caused by the proximity effect. Determination of the sound-source to microphone distance permits accurate compensation for both frequency response changes and distance-related signal level changes.

Provided are systems and methods for processing audio signals generated by microphones or other types of acoustic-to-electric transducers that convert sound into an electrical signal. The present systems and methods are adapted to provide automatic gain control and continuous proximity effect compensation of an audio signal based on the distance of the sound source to the microphone.

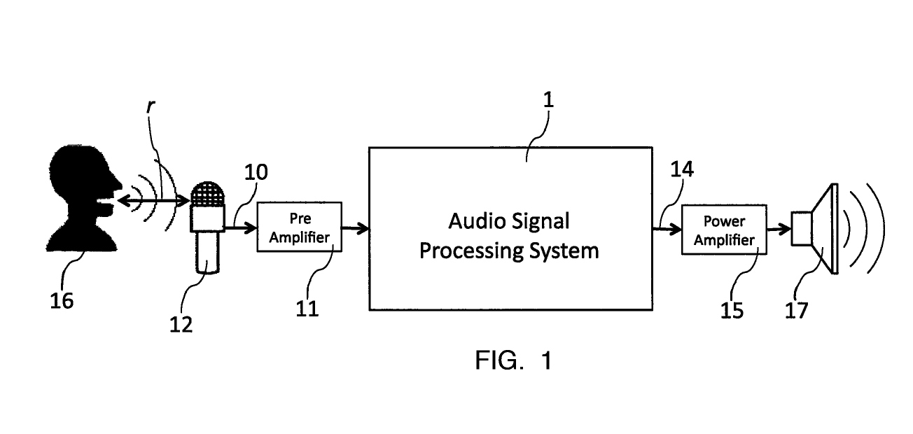

As shown in FIGS. 1-4, an audio signal processing system 1 receives an input audio signal 10 from a microphone 12 and generates an output audio signal 14. The microphone 12 converts sound produced by a sound source 16, which is a distance r from the microphone 12, into the input audio signal 10. As shown in FIGS. 1-4, the microphone 12 generates the input audio signal 10, which may be amplified by a pre-amplifier 11 and then received by the audio signal processing system 1. Although the pre-amplifier 11 is shown outside the audio signal processing system 1, it should be understood that the pre-amplifier 11 may be integrated into the audio signal processing system 1. Also, as shown in FIGS. 1-4, in some applications, the output audio signal 14 may be transmitted to a power amplifier 15, which amplifies and renders the output audio signal 14 on a loudspeaker 17. Although the power amplifier 15 is shown outside the audio signal processing system 1, it should be understood that the power amplifier 15 may be integrated into the audio signal processing system 1. In other applications, the output audio signal 14 may be transmitted or stored without amplification the audio signal processing system 1. For example, the output audio signal 14 may be transmitted over a communication network (e.g., internet) or stored on a storage device (i.e., recorded on a hard-drive, computer memory, computer readable media, etc.). In typical communication applications, the output audio signal 14 may be transmitted to a destination and then amplified and converted to an acoustic signal at the destination.

In the exemplary illustrations of FIGS. 1-4, the audio signal processing system 1 is shown as receiving the input audio signal 10 from the microphone 12 and generating the output audio signal 14 to be rendered on the loudspeaker 17. However, it should be understood by those skilled in the art that the signal processing system 1 may be integrated into the microphone 12. Also, although not shown, the signal processing system 1 may be integrated into a telephone comprising a microphone (e.g., IP conference telephones). While various embodiments have been described, it will be appreciated by those of ordinary skill in the art that modifications can be made to the various embodiments without departing from the spirit and scope of the invention as a whole.

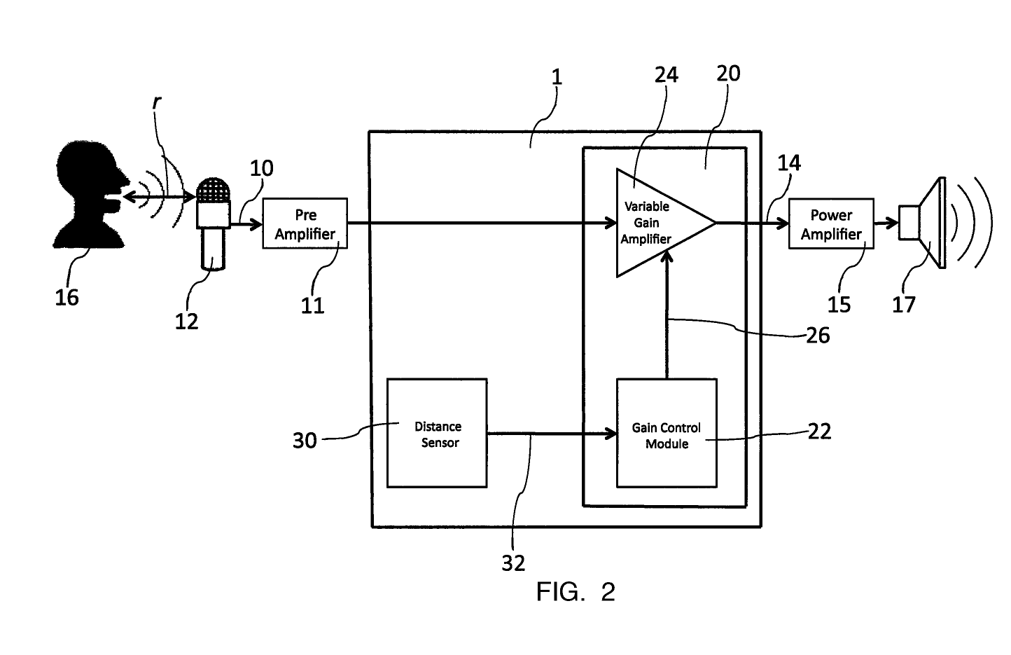

In accordance with one aspect of the present application, the audio signal processing system 1 may be configured to provide automatic gain control of an audio signal based on the distance of the sound source to the microphone. FIG. 2 shows an exemplary embodiment of the audio signal processing system 1 configured to provide automatic gain control of an audio signal based on the distance of the sound source to the microphone.

In accordance with the exemplary embodiment of FIG. 2, the audio signal processing system 1 comprises a gain controller 20 and a distance sensor 30. The gain controller 20 is configured to receive the input audio signal 10 from the microphone 12 and generate an output audio signal 14. The gain controller 20 is further configured to control the signal level (e.g., amplitude) of the output audio signal based on the distance r between the sound source 16 and the microphone 12. In the embodiment shown in FIG. 2, the signal processing system 1 includes the distance sensor 30, which is adapted to determine the distance r between the sound source 16 and the microphone 12. The distance sensor 30 generates a distance signal 32 communicating the distance r to the gain controller 20 so that the gain controller 20 can adjust the signal level (e.g., amplitude) of the output audio signal based on the distance r of the sound source 16 to the microphone 12. The distance sensor 30 may continuously determine the distance r between the sound source 16 and the microphone 12 and may continuously generate the distance signal 32 such that the gain controller 20 can continuously adjust the level of the output audio signal 14.

The distance sensor 30 can be based on video input (face detection), acoustic input (ultrasound), mechanic input (accelerometer), magnetic input or other input not perceivable by human senses. In alternative embodiments, the signal processing system 1 may be implemented without the distance sensor 30. For example, in one embodiment, the gain controller 20 may be configured to receive the distance signal 32 from a distance sensor that is external to the signal processing system 1. Thus, the signal processing system 1 may simply be configured to receive signals indicating the distance r between the sound source 16 and the microphone 12 from external sources in communication with the signal processing system 1.

In another embodiment, the gain controller 20 may be configured to determine the distance r between the sound source 16 and the microphone 12 based on the input audio signal 10 itself. For instance, the gain controller 20 may be configured to determine the distance r based on computational methods based on observed changes in signal features of the input audio signal 10 and the fact that the direct-to-reverberant sound energy ratio decreases as the distance r increases. For example, linear prediction residual peaks and skewness of the spectrum can be used to determine the distance r between the sound source 16 and the microphone 12. Also, If multiple microphones are available, additional properties can be exploited to estimate the distance r between the sound source 16 and the microphone 12. For example, two microphones in a binaural setup can be used to exploit the coherence between left and right signals. Further, if at least three microphones are available, sound arrival angles can be determined from correlation and then used for triangulation to determine the sound source location.

As will be understood by those skilled in the art, the gain controller 20 may be implemented in various hardware logic configurations to control the signal level (e.g., amplitude) of the output audio signal 14 based on the distance r between the sound source 16 and the microphone 12. In accordance with one exemplary embodiment, as shown in FIG. 2, the gain controller 20 may comprise a gain control module 22 and variable gain amplifier 24.

The gain control module 22 may be configured to execute computations to determine a desired gain for controlling the level of the output audio signal 14 based on the distance r between the microphone 12 and the sound source 16. The gain control module 22 may be further configured to generate and send a gain control signal 26 to the variable gain amplifier 24 based on the determination of the desired gain for controlling the level of the output audio signal 14. The variable gain amplifier 24 has a gain that can be adjusted by the gain control signal 26. Accordingly, the variable gain amplifier 24 may be configured to receive the gain control signal 26 generated by the gain control module 22 and control a gain of the variable gain amplifier 24 based on the gain control signal 26, such that the level of output signal 14 is adjusted according to the desired gain. Alternatively, the gain control module 22 may be implemented in conventional analog circuitry. It is to be understood that the gain when expressed on a logarithmic scale, such as dB), can be positive (i.e., amplification) or negative (i.e., attenuation); or alternatively, on a linear scale, the gain can be greater than 1 (i.e., amplification) or lesser than 1 (i.e., attenuation).

The gain control module 22, however, may be implemented in various suitable hardware logic configurations to determine a desired gain for controlling the level of the output audio signal 14 based on the distance r between the microphone 12 and the sound source 16, and to generate a corresponding gain control signal 26. In some embodiments, the gain control module 22 may comprise a digital signal processor or an application specific integrated circuit that is adapted to perform computations to determine the desired gain for controlling the level of the output signal 14 based on the distance r between the sound source 16 and the microphone 12. Accordingly, the gain control module 22 may be programmed or configured to execute various computations based on various algorithms defining the desired gain for the output audio signal 14 as a function of the distance r between the microphone 12 and the sound source 16.

It will be apparent to those skilled in the art that, depending on the specific mathematical models being implemented and the specific modeling assumptions being made, various suitable algorithms may be implemented in the gain control module 22 to determine the desired level of the output audio signal 14 based on the distance r between the sound source 16 and the microphone 12. For example, the gain control module 22 may be configured to determine the desired gain for controlling the level of the output audio signal 14 based on an inversely proportional relationship between the sound pressure level at the microphone and the distance r between the sound source 16 and the microphone 12. Following is an exemplary derivation of such an inversely proportional relationship between the sound pressure level at the microphone and the distance r between the sound source 16 and the microphone 12.

To approximate an acoustic wave field, two simple wave models are frequently used: the plane wave, originating from a plane source, and the spherical wave, originating from a point source. The spherical wave model can be applied to many practical sound sources. For example, the human voice closely produces a spherical wave in the frontal hemisphere. Focusing on voice transmission, the following derivation assumes a spherical sound field.

The sound pressure of a harmonic wave can be denoted in complex form by the following mathematical expression:

p(t)=\hat{p}·e^{j(ωr+φ}^{₀}) ((Equation 1)

with sound pressure amplitude \hat{p}, frequency f, ω=2πf, and phase φ₀. Note, from the theory of Fourier series, any steady state wave can be represented as a linear superposition of sine waves. With the above notation, the wave equation for a spherical wave can be written as:

$$\frac{{δ}^{2} p}{δ {r}^{2}} + \frac{2}{r} \frac{δ p}{δ r} = \frac{1}{{c}^{2}} \frac{{δ}^{2} p}{δ {t}^{2}}$$

with radius r (e.g., the distance from the sound source), speed of sound c, and time t. Evaluating the 2^{nd} derivative of p with respect to t, the following is obtained:

$$\frac{{δ}^{2} p}{δ {r}^{2}} + \frac{2}{r} \frac{δ p}{δ r} + {k}^{2} p = 0 \qquad ( Equation 2 )$$

where k=ω/c represents the wavenumber.

Eq. (2) is a homogenous differential equation 2^{nd} order with the solution for the outward moving wave

$$p ( r ) = {p}_{0} \frac{{r}_{0}}{r} {e}^{- j kr} \qquad ( Equation 3 )$$

where p₀ denotes the sound pressure at radius r₀. Equation 3 shows that if the radius r is doubled, the sound pressure drops to a half of its original value.

This property can also be derived in an alternate way from the inverse-square-law, which states that the sound intensity I (e.g., the sound energy per unit area) due to a spherical sound source is inversely proportional to the square of the distance from the sound source. Expressed in an equation for a point source emitting energy W, and an assumed sphere with radius r and resulting area A=4π², the following is obtained:

$$\begin{matrix}I = \frac{W}{A} \\ = \frac{W}{4 π {r}^{2}}\end{matrix} \qquad ( Equation 4 )$$

If the radius r is doubled, the sphere area is quadrupled. As a result, the intensity will drop to ¼ (e.g., the inverse of the squared distance ratio). Furthermore, since the average sound pressure p=\hat{p}/\sqrt{2} is proportional to the square root of the sound intensity I according to:

p=\sqrt{Iρ₀c} (Equation 5)

where τ₀ is the density and τ₀c the acoustic impedance of air, the sound pressure will drop to a half (e.g., 6 dB, in accordance with Equation 3).

To compensate for sound pressure variations caused by source-to-microphone distance variations, a gain inverse can be applied to the sound pressure ratio p(r)/p₀ given by Equation 3. A distance-based automatic gain control can be specified in this way as:

$$G ( r ) = {G}_{0} \frac{r}{{r}_{0}} {e}^{j kr} \qquad ( Equation 6 )$$

where G₀ denotes the desired nominal gain at radius r₀. Note, G(r) is complex, it may adjust the magnitude as well as the phase. Since the phase is linear, it represents simply a delay, the sound delay associated with the distance difference r−r₀. If the magnitude of the gain is considered, the following is obtained:

$$\vert G ( r ) \vert = {G}_{0} \frac{r}{{r}_{0}} \qquad ( Equation 7 )$$

Neglecting any diffuse sound field components, Equations 6 and 7 can be implemented in the gain controller 20/gain control module 22 to execute a distance-based automatic gain control based on an inverse-square-law.

Equation 3 assumes free field conditions, in other words, a direct sound field. However, if the sound source is located in a room, two sound fields may be produced: the direct sound field from the direct sound of the source, and the diffuse sound field from the reflected sound. To derive an automatic gain control equation for the desired gain that also takes the diffuse sound field into account, the sound energy densities of these two sound fields are added up. The sound energy density for a sound pressure p is given by

$$D = \frac{{p}^{2}}{ρ {c}^{2}} \qquad ( Equation 8 )$$

For the direct sound, from Equations 4 and 5, the following is obtained:

$$D = \frac{W}{4 π {r}^{2} c} \qquad ( Equation 9 )$$

For the diffuse sound, the sound energy density is given in accordance by:

$${D}^{′ } = \frac{4 W ( 1 - \overline{α} )}{cS \overline{α}} \qquad ( Equation 10 )$$

where α̅ denotes the average sound absorption coefficient, and S the room surface area. The average absorption coefficient α̅ is the area-weighted average of the individual absorption coefficients α₁,

$$\overline{α} = \frac{1}{S} {\sum }_{i}^{ } {S}_{i} {α}_{i}$$

While the direct sound field depends on the radius (i.e., the distance to the sound source) the diffuse sound field does not. Adding the sound energy densities of direct and diffuse sound field, multiplying with ρ₀c², and taking the square root results in the sound pressure

$$p ( r ) = \sqrt{W {ρ}_{0} c ( \frac{1}{4 π {r}^{2}} + \frac{4 ( 1 - \overline{α} )}{S \overline{α}} )} \qquad ( Equation 11 )$$

With Equation 11, the ratio of the sound pressures at radius r and r₀ can be determined,

$$\frac{p ( r )}{p ( {r}_{0} )} = \sqrt{\frac{R + 1 / {r}^{2}}{R + 1 / {r}_{0}^{2}}} \\ where \\ R = \frac{16 ( 1 - \overline{α} ) π}{S \overline{α}} . \qquad ( Equation 12 )$$

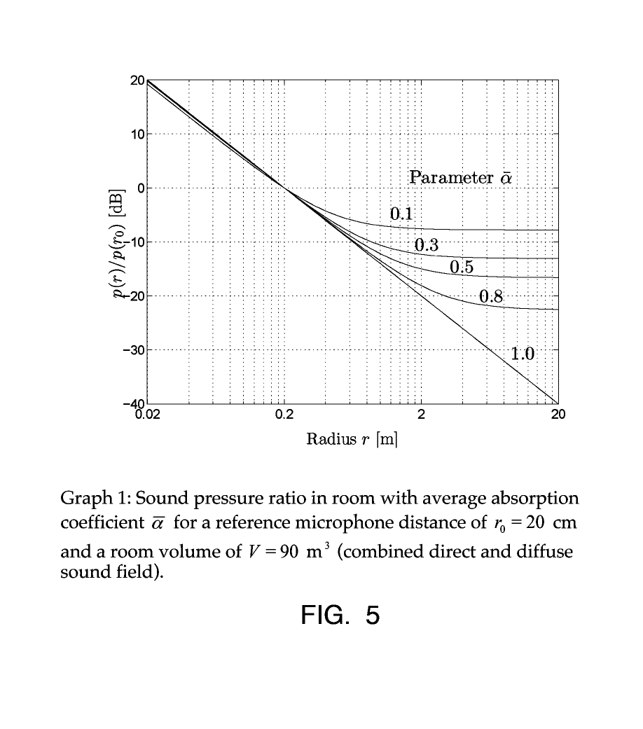

Given the room dimensions, the room surface S and the room volume V can be specified. FIG. 5 shows Graph 1, which illustrates the sound pressure ratio p(r)/p(r₀) stated by Equation 12.

For α̅=1, e.g., a direct sound field, the pressure ratio may be inversely proportional to the radius throughout the entire range, reflected by the straight 1/r line in the double-logarithmic plot. As α̅ decreases, the sound pressure level of the diffuse sound field increases. Furthermore, for a small radius, the direct sound pressure dominates, and vice versa, for a large radius, the diffuse sound pressure dominates. The radius or distance for which the sound pressure levels of direct and diffuse sound field are equal is called critical distance or reverberation distance. If the speaker-to-microphone distance stays well within the critical distance, the diffuse sound field can be neglected in the computation for the desired gain and Equation 7 can be applied.

Since the gain applied for the automatic gain control is the inverse of the sound pressure ratio (i.e., Equation 12) the desired gain for the combined direct and diffuse sound fields becomes:

$${G}^{′} ( r ) = {G}_{0} \sqrt{\frac{R + 1 / {r}_{0}^{2}}{R + 1 / {r}^{2}}} \qquad ( Equation 13 )$$

In analyzing Equation 13, the two extrema α̅=0 and α̅=1 for the average absorption coefficient are of particular interest. For α̅=1 (complete absorption), R=0, therefore

$${G}^{′} ( r ) {\vert}_{\overline{α} = 1} = {G}_{0} \frac{r}{{r}_{0}} \qquad ( Equation 14 )$$

For this case, there is only the direct sound field. Therefore, a result identical to Equation 7 may be obtained. For the other extremum, α̅=0 (no absorption), R=∞, and

$${lim}_{\overline{α} \to 0} {G}^{′} ( r ) = {G}_{0}$$

With no absorption (e.g., completely reflecting walls) the sound pressure level will no longer depend on the distance to the sound source. Note, assuming no absorption by the medium, no sound energy would be lost in this case, and sound pressure would build up over time. In practice, however, a small amount of absorption will ensure an equilibrium.

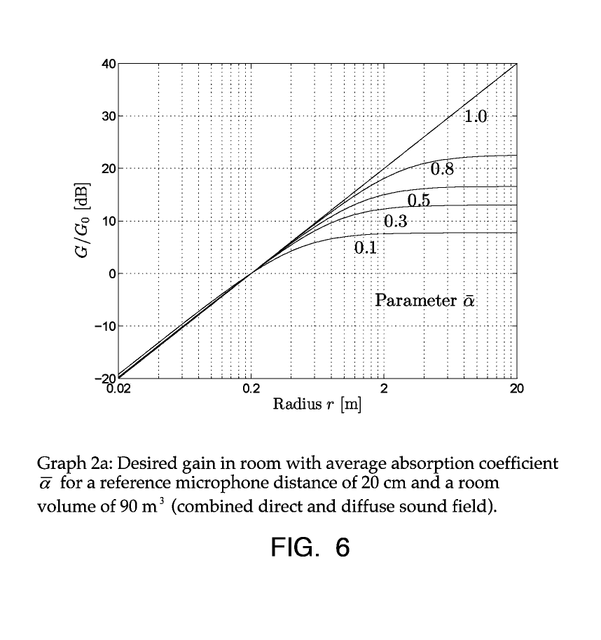

The desired gain in room conditions given in Equation 13 is illustrated in Graph 2a shown in FIG. 6.

If a maximum gain error of 3 dB is tolerable, which occurs at the critical distance r_{c}, each gain curve can be approximated by two linear portions. The first portion according to the inverse of the radius associated with the direct sound field, and the second portion a constant, associated with the diffuse field,

$${G}^{′} ( r ) \approx \{ \begin{matrix}{G}_{0} \frac{r}{{r}_{0}} & ; if r \leq {r}_{c} \\ {G}_{0} \frac{{r}_{c}}{{r}_{0}} & ; else\end{matrix} \qquad ( Equation 15 )$$

For r≦r_{c}, the gain required to adjust to the direct sound field may be applied; for r>r_{c}, a constant gain identical to the gain required to adjust for the direct sound field at r_{c} is applied.

In addition to Equations 12 and 13, an analytical expression for the sound pressure ratio and the desired gain as a function of the critical distance r_{c} may be of interest. These equations can be derived in the following way. To determine the critical distance r_{c}, the energy density of the direct sound Equation 9 is set equal to the energy density of the diffuse sound, Equation 10, and solve for r_{c},

$${r}_{c} = \frac{1}{4} \sqrt{\frac{S \overline{α}}{π ( 1 - \overline{α} )}} \qquad ( Equation 16 )$$

Alternatively, r_{c} can be determined from the standard deviation of the energy spectral response. Likewise, the direct sound field pressure p₀ can be measured at a radius r₀ close to the source, and the diffuse field sound pressure p_{D} far from the source, both through sound level measurements, then r_{c}=r₀·p₀/p_{D} can be applied, an equation which can be derived from Equation 3. With Equations 12 and 16, the pressure ratio can be written in the following form:

$$\frac{p ( r )}{p ( {r}_{0} )} = K \sqrt{1 + {( \frac{{r}_{c}}{r} )}^{2 }} \qquad ( Equation 17 )$$

whereby the factor K is given by:

$$K = {( 1 + \frac{1}{{Rr}_{0}^{2}} )}^{- \frac{1}{2}} \qquad ( Equation 18 )$$

Equation 17 has the magnitude form of an inverse first order low-pass with respect to parameter r, apparent also from Graph 1.

Taking the inverse of the right term in Equation 17, the desired gain can be expressed in terms of the critical distance,

$${G}^{′} ( r ) = {{G}_{0} ( K \sqrt{1 + {( \frac{{r}_{c}}{r} )}^{2}} )}^{- 1} \qquad ( Equation 19 a )$$

which is a 1^{st} order low-pass with a cut-off or transition radius of r_{c}, and a gain further depending on the room absorption and the desired reference distance. Accordingly, Equation 19a can be implemented in the gain controller 20/gain control module 22 to execute a distance-based automatic gain control that also takes the diffuse sound field into account. For simplicity, a purely spherical sound source may be assumed throughout the derivations described herein. However, a directivity factor γ can readily be included by using the effective critical distance r^{}_{c}=r_{c}√γ.

The computation of G′(r) via Equation (19) may be impractical in an application, since it requires both the critical distance r_{c} and the additional computation of K. Recognizing that the curves in Graph 2a are variants of first order high-pass filters, G′ (r) may be derived from the transfer function of such a filter, i.e.,

$${G}^{′} ( r ) = {G}_{0} \frac{{r}_{c}}{{r}_{0}} \cdot \frac{1}{1 + j {r}_{c} / r}$$

If only the magnitude is considered, the following is obtained:

$${G}^{′} ( r ) = {G}_{0} \frac{{r}_{c}}{{r}_{0}} \cdot \frac{1}{\vert 1 + j {r}_{c} / r \vert} \qquad ( Equation 19 b )$$

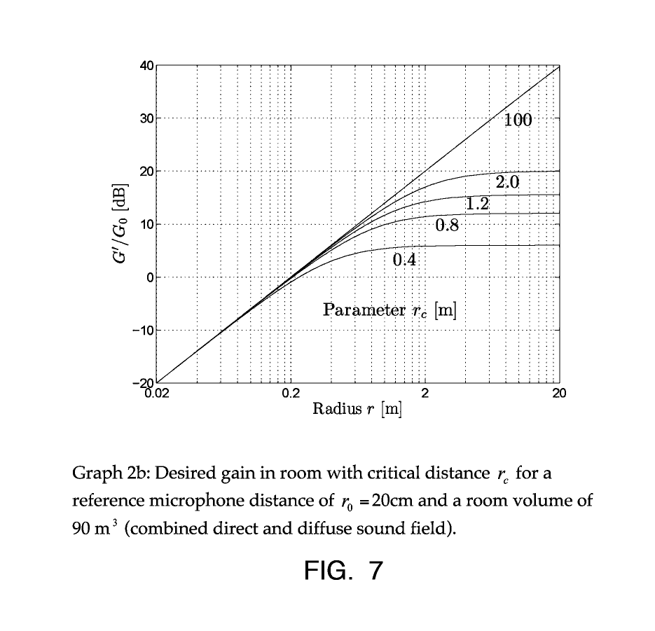

FIG. 7 illustrates Graph 2b, which shows the desired gain with the critical distance r_{c} as a parameter. For this illustration, the parameters r_{c} were chosen for easy verification of the critical distance r_{c} on the plot (3 dB point). Furthermore, the parameters were chosen such that a similar set of curves as in Graph 2a were generated.

Consider now the parameter, r_{c}=0.4m, representing a room with extreme reverberation. In this case, the gain transition (3 dB point) is at 0.4m. Beyond this distance, the gain should flatten out. In other words, if the sound source is moved beyond 0.4m, the desired distance-based gain G′ (r) may no longer need to increase. On the other hand, consider the parameter r_{c}=100m, representing a room with extreme absorption. In this case, the gain needs to increase throughout the entire range of the plotted sound source distance of 0.02m to 20m. Note, for the latter case, Equation (7) provides the same results over the range shown.

To summarize, the case of a direct sound field only and the case of a combined direct and diffuse sound field are compared. For the direct sound field case, Equation (7) shows that only the speaker-microphone distance r and the nominal distance r₀ are relevant to determine the distance-based gain, whereas for the combined sound field, Equation (19b) shows that r, r₀, and the critical distance r_{c} may be relevant for the distance-based gain.

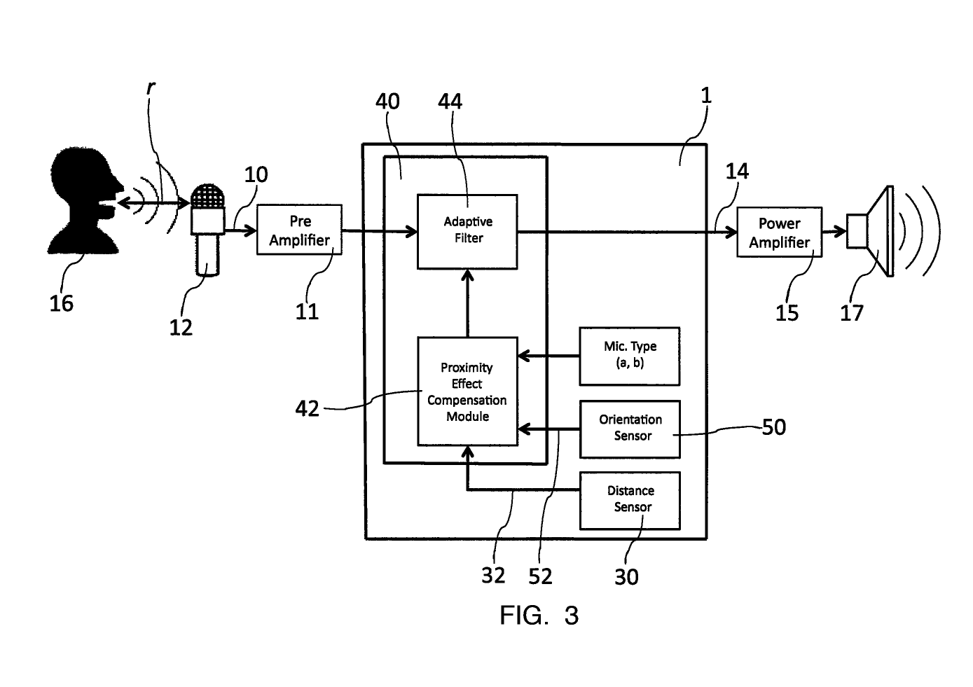

In accordance with another aspect of the present application, the audio signal processing system 1 may be configured to provide continuous proximity-effect compensation of an audio signal based on the distance of the sound source to the microphone. FIG. 3 shows an exemplary embodiment of the audio signal processing system 1 configured to provide continuous proximity-effect compensation of an audio signal based on the distance of the sound source to the microphone.

In accordance with the exemplary embodiment of FIG. 3, the audio signal processing system 1 comprises a frequency response controller 40 and a distance sensor 30. The frequency response controller 40 is configured to receive the input audio signal 10 from the microphone 12 and generate an output audio signal 14. The frequency response controller 40 is further configured to control the frequency spectrum of the output audio signal based on the distance r between the sound source 16 and the microphone 12. In the embodiment shown in FIG. 3, the signal processing system 1 may include the distance sensor 30, which is adapted to determine the distance r between the sound source 16 and the microphone 12. The distance sensor 30 generates a distance signal 32 communicating the distance r to the frequency response controller 40 so that the frequency response controller 40 can adjust the frequency spectrum of the output audio signal based on the distance r of the sound source 16 to the microphone 12. The distance sensor 30 may continuously determine the distance r between the sound source 16 and the microphone 12 and may continuously generate the distance signal 32 such that the frequency response controller 40 can continuously adjust the frequency spectrum of the output audio signal 14.

The distance sensor 30 can be based on video input (face detection), acoustic input (ultrasound), mechanic input (accelerometer), magnetic input or other input not perceivable by human senses. In alternative embodiments, the signal processing system 1 may be implemented without the distance sensor 30. For example, in one embodiment, the gain controller 20 may be configured to receive the distance signal 32 from a distance sensor that is external to the signal processing system 1. Thus, the signal processing system 1 may simply be configured to receive signals indicating the distance r between the sound source 16 and the microphone 12 from external sources in communication with the signal processing system 1.

In another embodiment, the gain controller 20 may be configured to determine the distance r between the sound source 16 and the microphone 12 based on the input audio signal 10 itself. For instance, the gain controller 20 may be configured to determine the distance r based on computational methods based on observed changes in signal features of the input audio signal 10 and the fact that the direct-to-reverberant sound energy ratio decreases as the distance r increases. For example, linear prediction residual peaks and skewness of the spectrum can be used to determine the distance r between the sound source 16 and the microphone 12. Also, If multiple microphones are available, additional properties can be exploited to estimate the distance r between the sound source 16 and the microphone 12. For example, two microphones in a binaural setup can be used to exploit the coherence between left and right signals. Further, if at least three microphones are available, sound arrival angles can be determined from correlation and then used for triangulation to determine the sound source location.

Also, the audio signal processing system 1 may optionally comprise an orientation sensor 50, which is adapted to determine an angle of incidence θ of the sound with respect to the microphone 12. Additionally, the frequency response controller 40 may be further configured to control the frequency spectrum of the output audio signal based on an angle of incidence of the sound with respect to the microphone 12. The orientation sensor 50 generates an orientation signal 52 communicating the angle of incidence θ to the frequency response controller 40 so that the frequency response controller 40 can adjust the frequency spectrum of the output audio signal based on the angle of incidence θ of the sound with respect to the microphone 12. The orientation sensor 50 may continuously determine the angle of incidence θ of the sound with respect to the microphone 12 and may continuously generate the orientation signal 52 such that the frequency response controller 40 can continuously adjust the frequency spectrum of the output audio signal 14.

As will be understood by those skilled in the art, the frequency response controller 40 may be implemented in various hardware logic configurations to control the frequency spectrum of the output audio signal 14 based on the distance r between the sound source 16 and the microphone 12, and optionally the angle of incidence θ of the sound with respect to the microphone 12. In accordance with one exemplary embodiment, as shown in FIG. 3, the frequency response controller 40 may comprise a proximity-effect compensation module 42 and an adaptive filter 44.

The proximity-effect compensation module 42 may be configured to execute computations to determine a desired frequency spectrum for the output audio signal 14 (i.e., determine a corner frequency) based on the distance r between the microphone 12 and the sound source 16, and optionally the angle of incidence θ of the sound with respect to the microphone 12. The proximity-effect compensation module 42 may be further configured to generate and send a filter control signal 46 to the adaptive filter 44 based on the determination of the desired frequency spectrum for the output audio signal 14 (i.e., corner frequency). For instance, the filter control signal 46 may specify a compensation filter to be implemented by the adaptive filter 44 for achieving the desired frequency spectrum for the output audio signal 14 (i.e., corner frequency), which compensates for the proximity effect. Accordingly, the adaptive filter 44 may be configured to receive the filter control signal 46 generated by the proximity-effect compensation module 42 and control a filter of the adaptive filter 44 and adjust the frequency spectrum for the output audio signal 14 based on the filter control signal 46. The adaptive filter 44 may be an adaptive high-pass filter that can be adjusted by the filter control signal 46.

The proximity-effect compensation module 42, however, may be implemented in various suitable hardware logic configurations to determine a desired frequency spectrum for the output audio signal 14 based on the distance r between the microphone 12 and the sound source 16, and optionally the angle of incidence θ of the sound with respect to the microphone 12, and to generate a filter control signal 46. In some embodiments, the proximity-effect compensation module 42 may comprise a digital signal processor or an application specific integrated circuit that is adapted to perform computations to determine the desired frequency spectrum for the output signal 14 based on the distance r between the sound source 16 and the microphone 12, and optionally the angle of incidence θ of the sound with respect to the microphone 12, and to determine a corresponding compensation filter.

Accordingly, the proximity-effect compensation module 42 may be programmed or configured to execute various computations based on various algorithms defining the desired frequency spectrum for the output audio signal 14 as a function of the distance r between the microphone 12 and the sound source 16, and optionally the angle of incidence θ of the sound with respect to the microphone 12, and defining a corresponding compensation filter.

It will be apparent to those skilled in the art that, depending on the specific mathematical models being implemented and the specific modeling assumptions being made, various suitable algorithms may be implemented in the proximity-effect compensation module 42 to determine the desired frequency spectrum of the output audio signal 14 based on the distance r between the sound source 16 and the microphone 12, and optionally the angle of incidence θ of the sound with respect to the microphone 12, and to determine a corresponding compensation filter. Following is an exemplary derivation of a relationship between the desired frequency spectrum of the output audio signal 14 and the distance r between the sound source 16 and the microphone 12, and optionally the angle of incidence θ of the sound with respect to the microphone 12, and an exemplary derivation of a corresponding compensation filter.

The proximity effect is a gradual increase of the low frequency output as a pressure-gradient microphone approaches a sound source. It occurs for pressure-gradient microphones (e.g., directional microphones) and if exposed to a wave field with curvature components (e.g., spherical components). The proximity effect does not occur for pressure microphones, nor does it occur for any microphone type in a plane wave field.

The force acting to move the diaphragm of a pressure-gradient microphone may be represented as:

$${F}_{D} = - A \frac{δ p}{δ r} Δ l cos θ \qquad ( Equation 20 )$$

where A denotes the area of the diaphragm, p the sound pressure, θ the angle between the direction of the sound wave and the normal of the diaphragm, and Δl the effective distance between the two sides of the diaphragm.

Using Equation 3, the pressure gradient in Equation 20 for a spherical sound wave can be determined,

$$\frac{δ p}{δ r} = - {p}_{0} \frac{{r}_{0}}{r} {e}^{j kr} ( \frac{1}{r} + j k ) \qquad ( Equation 21 )$$

The first term in the sum is sometimes called the near-field gradient and the second term the far-field gradient. The near-field gradient is frequency independent and caused by the amplitude decrease with distance, whereas the far-field gradient is frequency-dependant and caused by phase difference. Most relevant here is that the first term causes the proximity effect.

The near-field term is relevant for low frequencies. If the low frequency range is ignored for a moment, the pressure gradient as given in Equation 21 increases proportional to the frequency, as a result of the contribution of k=ω/c . For this reason, a basic pressure-gradient device requires equalization with a term proportional to 1/ω, a task that can be achieved either electronically by an analog/digital filter or mechanically by a mass-controlled ribbon or diaphragm. To relate the gradient Equation 21 to the velocity, the gradient is equalized in a suitable way (i.e., both sides of Equation 21 are multiplied with the term 1/jωρ₀),

$$\frac{δ p}{δ r} \frac{1}{{jωρ}_{0}} = {p}_{0} \frac{{r}_{0}}{r} {e}^{j kr} \frac{1}{{ρ}_{0} c} ( 1 - \frac{j}{kr} ) \qquad ( Equation 22 )$$

Recall that the velocity can be invoked via the linear Euler equation,

$$- ∇ p = {ρ}_{0} \frac{δ v}{δ t} \qquad ( Equation 23 )$$

where ∇ denotes the gradient, v the particle velocity, and ρ₀ the static air density. Using spherical coordinates and taking the derivative of the velocity of an assumed harmonic wave, Equation 23 becomes:

$$- \frac{δ p ( r , t )}{δ r} = {jωρ}_{0} v ( r , t ) \qquad ( Equation 24 )$$

Inserting Equation 21 into Equation 24 and resolving for the velocity, the following is obtained:

$$v ( r , t ) = {p}_{0} \frac{{r}_{0}}{r} {e}^{j kr} \frac{1}{{p}_{0} c} ( 1 - \frac{j}{kr} ) \qquad ( Equation 25 )$$

While Equation 22 is derived from the requirement for equalization of the pressure gradient and as such, represents the desired output of a gradient microphone, Equation 25 is derived from the linear Euler equation. Both Equations 22 and 25 being equal, the output of a gradient microphone is proportional to the velocity. Hence, the gradient microphone may also be called velocity microphone.

From Equation 25, it can be seen that the velocity of a spherical wave may be complex in the near-field (i.e., pressure and velocity are not in phase). Furthermore, for k>>1 (i.e., distances large compared to the wavelength) the spherical wave field approaches a plane wave field governed by the specific acoustic impedance Z=ρ₀c and the relationship p=Z·v.

The term 1−j/kr in Equation 25 causes the proximity effect. For convenience, the following is introduced:

$${H}_{0} ( kr ) = 1 - \frac{j}{kr} \qquad ( Equation 26 )$$

to refer to the transfer function of the proximity effect. Note however, Equation 26 is valid for a pure pressure-gradient microphone (e.g., figure-8 microphone). To derive a general transfer function for the proximity effect, angle θ is used as specified in association with Equation 20. Recall that the polar pattern R(θ) for a first-order microphone can be denoted as:

R(θ)=a+b·cos θ (Equation 27)

whereby the parameters a≦1 and b≦1 (with a+b=1) specify the directivity of the microphone. The omnidirectional microphone is determined by a=1, b=0; the cardioid by a=0.5, b=0.5; the supercardioid by a=0.37, b=0.63; the hypercardioid by a=0.25, b=0.75; and the figure-8 by a=0, b=1. In other words, a 1^{st} order pressure-gradient microphone can be represented as a weighted sum of two microphone signals, the first from an omnidirectional microphone with weighting factor a and the second from a figure-8 microphone with weighting factor b. Accordingly, the proximity effect can be specified in terms of the factors a and b,

H(kr)=a+b cos θH₀(kr) (Equation 28)

Since the omnidirectional microphone has no proximity effect, its contribution is frequency-independent.

Inserting H₀(kr) from Equation 26 into and Equation 28, the following is obtained:

$$H ( kr ) = a + b cos θ - j \frac{b cos θ}{kr} \qquad ( Equation 29 )$$

The corner frequency for this 1^{st} order filter is:

$${f}_{c} = \frac{c}{2 π r} \cdot \frac{b cos θ}{a + b cos θ} \qquad ( Equation 30 )$$

where c is the speed of sound. The proximity effect is often stated in its magnitude form for the special case of a=0, b=1 (i.e., pure pressure-gradient microphone) and θ=0 (i.e., |H(kr)∥_{θ=0,b=1}={square root over (1+1/(kr)²))}. With Equation 29, this magnitude response can be generalized as:

$$\vert H ( kr ) \vert = \sqrt{{( a + b co θ )}^{2} + {( \frac{b cos θ}{kr} )}^{2}}$$

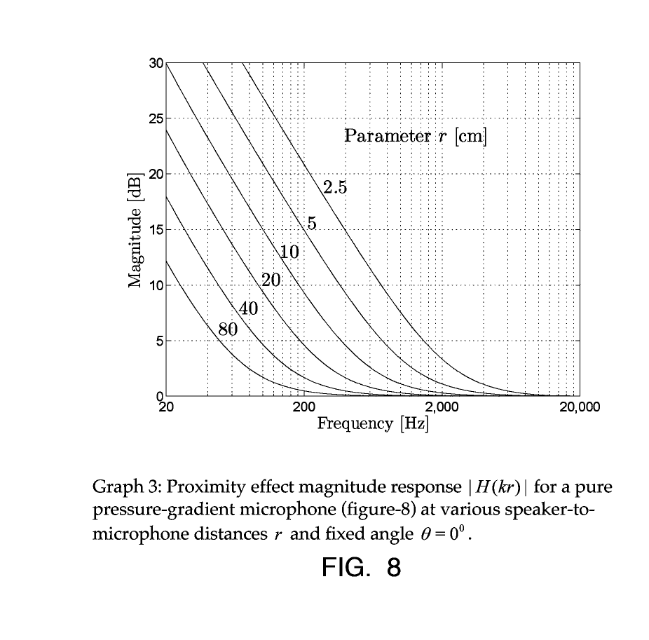

To illustrate the effect of the parameters r, b, and θ, the magnitude frequency response of the proximity effect is plotted in Graph 3, shown in FIG. 8, for various speaker-to-microphone distances r, at fixed directivity b=1 (i.e., for a pure pressure-gradient microphone) and fixed angle θ=0.

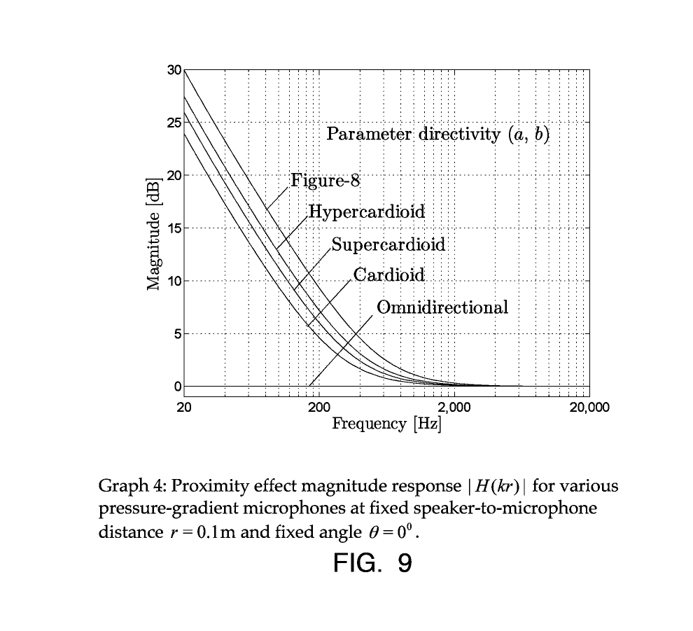

FIG. 9 illustrates Graph 4, which shows the proximity effect for various pressure-gradient microphones at fixed speaker-to-microphone distances.

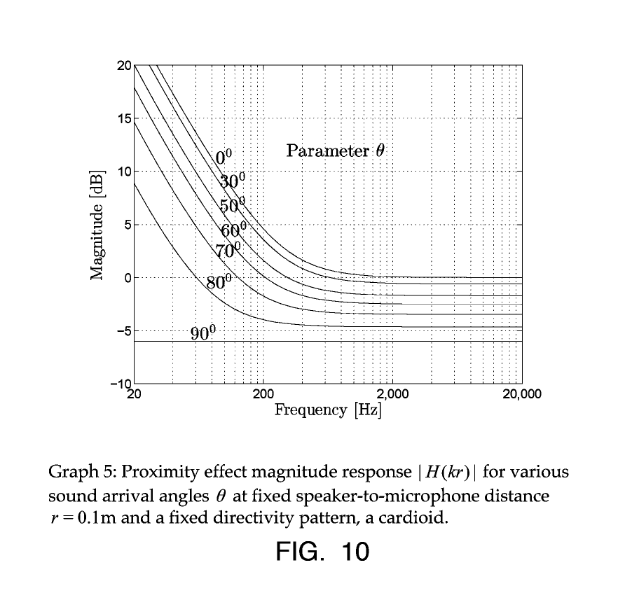

Finally, FIG. 10 illustrates Graph 5, which shows the proximity effect for various sound arrival angles θ at fixed speaker-to-microphone distance and fixed directivity (cardioid).

Taking the inverse of H(kr) (Equation 29), the compensation filter for the proximity effect can be specified as:

$$C ( kr ) = \frac{kr}{kr ( a + b cos θ ) - j b cos θ} \qquad ( Equation 31 )$$

The magnitude responses of these filters are apparent from Graphs 3-5, the curves in these plots simply need to be mirrored at the O-dB magnitude line. If the speaker-to-microphone distance r and the type of pressure-gradient microphone (e.g., cardioid, supercardioid, hypercardidod) is known, the corresponding compensation filter C(kr) can be applied.

Accordingly, Equation 30 can be implemented in the frequency response controller 40/proximity-effect compensation module 42 to determine a desired frequency spectrum for the output audio signal 14 (i.e., corner frequency) based on the distance r between the microphone 12 and the sound source 16, and optionally the angle of incidence θ of the sound with respect to the microphone 12. Further, Equation 31 can be used to define the compensation filter, which is specified in the filter control signal 46, to be implemented in the adaptive filter 44 to adjust the frequency spectrum of the output audio signal 14 and compensate for the proximity effect.

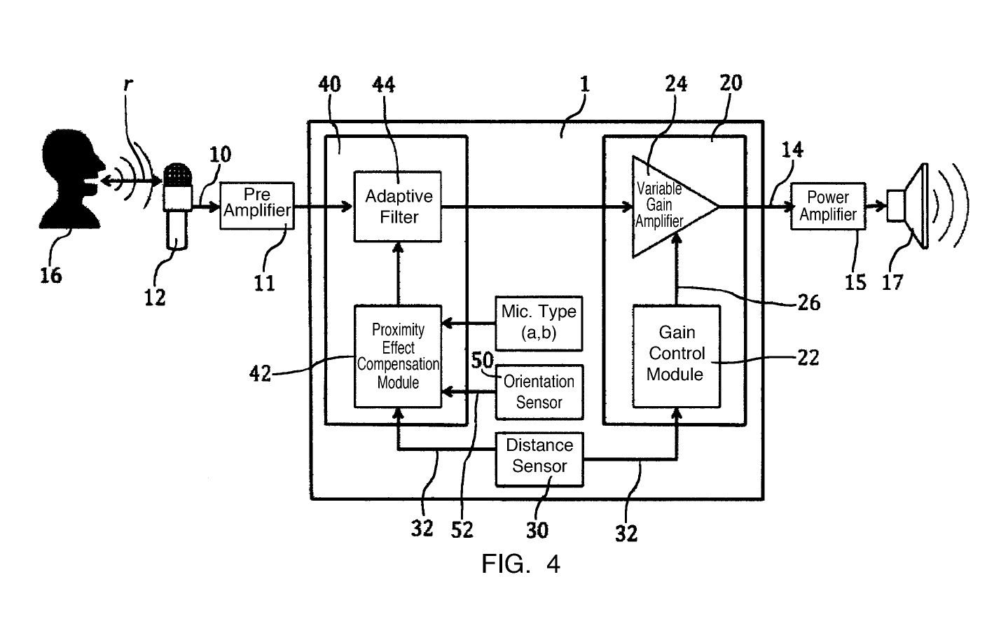

In accordance with yet another aspect of the present application, the audio signal processing system 1 may be configured to provide both automatic gain control of an audio signal and continuous proximity-effect compensation of the audio signal based on the distance of the sound source to the microphone. FIG. 4 shows an exemplary embodiment of the audio signal processing system 1 configured to provide both automatic gain control of an audio signal and continuous proximity-effect compensation of the audio signal based on the distance of the sound source to the microphone. As shown in the exemplary embodiment of FIG. 4, the audio signal processing system 1 comprises the gain controller 20 as described above with reference to the exemplary embodiment of FIG. 2 and the frequency response controller 40 as described above with reference to the exemplary embodiment of FIG. 3. Additionally, the audio signal processing system 1 comprises the distance sensor 30 as described above with reference to the exemplary embodiments FIGS. 2 and 3. Further, the audio signal processing system 1 may optionally comprise the orientation sensor 50 as described above with reference to the exemplary embodiment of FIG. 3. The gain controller 20, the frequency response controller 40, the distance sensor 30 and the orientation sensor 50 may be configured and may operate in substantially the same manner described above with reference to the exemplary embodiments of FIGS. 2 and 3.

As shown in the exemplary embodiment of FIG. 4, the audio signal processing system 1 is configured to provide both automatic gain control of an audio signal and continuous proximity-effect compensation of the audio signal based on the distance of the sound source to the microphone. As shown in the embodiment of FIG. 4, the audio signal processing system 1 receives the input audio signal 10 from the microphone 12. The automatic gain controller 20 of the audio signal processing system 1 is configured to provide automatic gain control to normalize signal level changes of the input audio signal 10 caused by changes in the distance between the audio source 16 and the microphone 12. More particularly, the gain controller 20 is configured to control the signal level (e.g., amplitude) of the output audio signal based on the distance r between the sound source 16 and the microphone 12. The frequency response controller 40 of the audio signal processing system 1 is configured to compensate for undesired bass response variations in the input audio signal 10 caused by the proximity effect by adjusting the frequency of the input audio signal 10. More particularly, the frequency response controller 40 is configured to control the frequency spectrum of the output audio signal based on the distance r between the sound source 16 and the microphone 12. Additionally, the frequency response controller 40 may be further configured to control the frequency spectrum of the output audio signal based on an angle of incidence of the sound with respect to the microphone 12.

As shown in FIG. 4, the distance sensor 30 generates a distance signal 32 communicating the distance r to the gain controller 20 so that the gain controller 20 can adjust the signal level (e.g., amplitude) of the output audio signal based on the distance r of the sound source 16 to the microphone 12 and communicating the distance r to the frequency response controller 40 so that the frequency response controller 40 can adjust the frequency spectrum of the output audio signal based on the distance r of the sound source 16 to the microphone 12. The distance sensor 30 may continuously determine the distance r between the sound source 16 and the microphone 12 and may continuously generate the distance signal 32 such that the gain controller 20 can continuously adjust the level of the output audio signal 14 and such that the frequency response controller 40 can continuously adjust the frequency spectrum of the output audio signal 14. Also, the audio signal processing system 1 may optionally comprise an orientation sensor 50, which is adapted to determine an angle of incidence θ of the sound with respect to the microphone 12. The orientation sensor 50 generates an orientation signal 52 communicating the angle of incidence θ to the frequency response controller 40 so that the frequency response controller 40 can adjust the frequency spectrum of the output audio signal based on the angle of incidence θ of the sound with respect to the microphone 12. The orientation sensor 50 may continuously determine the angle of incidence θ of the sound with respect to the microphone 12 and may continuously generate the orientation signal 52 such that the frequency response controller 40 can continuously adjust the frequency spectrum of the output audio signal 14.

Using both Equations 19 and 31 described above, the following is obtained

Gₜₒₜ(kr)=G′(r)·C(kr) (Equation 32)

the distance-based automatic gain control with proximity-effect compensation. Accordingly, Equation 32 can be implemented in the audio signal processing system 1 to provide both automatic gain control of an audio signal and continuous proximity-effect compensation of the audio signal based on the distance of the sound source to the microphone.

In practice, sound sources are not infinitely small. That is, if a voice is recorded from a centimeter distance from the mouth, a sound field curvature corresponding to a point source with center right at the mouth cannot be assumed. A simple way to model a finite sound source is to account for the sound source dimensions. Assuming a sphere for the sound source (e.g., a human head), a sound source radius rₛ corresponding to the radial dimension of the sound source (e.g., a human head) can be associated with the sound source as follows:

r=r′+rₛ (Equation 33)

where r is the radius used in Equations 7-32 and r′ is the measured distance from the sound source (e.g., the mouth). In other scenarios, rₛ may correspond to another dimension of the sound source, not a radial dimension. For example, in some scenarios, the sound source may be a box speaker having width, depth and height dimensions. Accordingly, the dimension corresponding to rₛ may be a non-radial dimension (e.g., depth) or some portion thereof.

### EXAMPLES

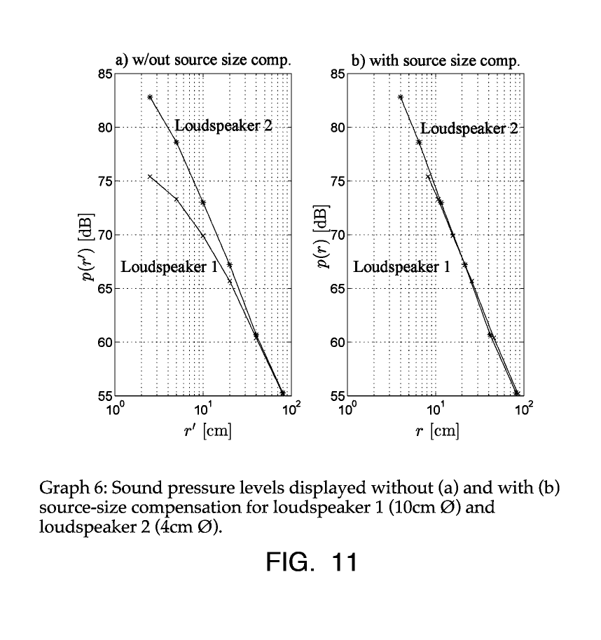

To verify the concept of distance-based automatic gain control, the inventor first investigated the relevance of the source size in Equation 33 using two loudspeakers of different sizes, a 10-cm full-range speaker (Yamaha MS101II) here referred to as loudspeaker 1, and a 4-cm full-range speaker (HP USB mini) referred to as loudspeaker 2. Playing white noise on each loudspeaker individually, the inventor recorded the sound with an omnidirectional microphone (Earthworks M23) sequentially placed at six logarithmically-spaced distances, r′=2.5 cm, 5 cm, 10 cm, 20 cm, 40 cm, and 80 cm. Graph 6 shows the sound pressure levels calculated from the recorded signals and displayed with and without source-size compensation. Recall from Equation 3 that a point source is characterized by a 6 dB sound pressure role-off per doubled distance (or 20 dB per decade). Considering now Graph 6, the inventor notes that the smaller loudspeaker behaves, as expected, in a wide range (5 cm . . . 80 cm) similar to a point source. In order to apply source-size compensation (Graph 6), necessary in particular for the larger loudspeaker 1, the inventor first needed to determine the source radius rₛ. The inventor assumed that rₛ could be set to half the loudspeaker enclosure width (i.e., 14 cm/2 and 5 cm/2), which predominantly determines the horizontal wave field. To verify this assumption, the inventor found the source radius that is optimal in a least square sense. Using rₛ as a curve fitting parameter, the inventor determined rₛ such that it minimizes the sum of the squared errors with respect to the best positioned line with a −60 dB/dec slope. This way, the inventor obtained rₛ=5.7 cm for loudspeaker 1 and rₛ=1.5 cm for loudspeaker 2, results that are indeed similar to the corresponding loudspeaker-enclosure widths. FIG. 11 illustrates Graph 6, which shows the sound pressure levels when plotted against the source-size compensated radius (i.e., an offset to the abscissa), both curves closely approximating a line and hence modeling a point source. Note, the sound pressure level curves derived from half the enclosure width (not shown in Graph 6) deviate marginally (<1 dB) from the optimal case.

Since Equation 12 predicts a sound-pressure role-off as shown in Graph 1, the inventor concluded from comparing Graph 6 with Graph 1 that the critical distance r_{c} is greater than 80 cm in the measurements associated with Graph 6. Therefore, the inventor simply used Equation 7, instead of Equation 13, 15, or 19 to calculate the distance-based desired gain for these recordings. In fact, for telepresence use cases, the speaker is often within r<80 cm, in which case the assumption r<r_{c} is usually valid, making the distance-based automatic gain control calculation straight-forward (i.e., Equation 7).

To obtain recorded speech signals, the inventor removed the loudspeaker and a male speaker took its position. The speaker announced the microphone distance with the phrase “The microphone is now at cm”. Three microphones were used to record this case: a cardioid (AKG Perception 170), an omnidirectional microphone (Earthworks M23), both mounted on a slider with a distance scale to measure the distance to the speaker; and an additional control microphone (AKG Perception 170), set up at fixed distance to verify that the speaker spoke at the same volume for each microphone distance.

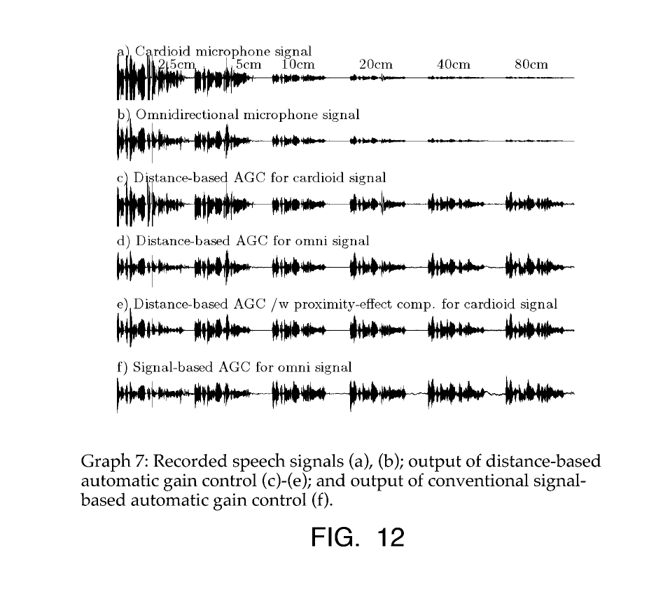

FIG. 12 illustrates Graph 7, which shows the recorded signals for the cardioid (a) and omni (b) at the six different distances, each distance represented by a 3.4 s interval in the plots. The processed signals are shown in (c)-(f). For both desired gain computation and proximity-effect compensation, rₛ was set to 2.5 cm (Equation 33). Furthermore, with the condition r<r_{c} being confirmed (see Graph 6), it was adequate to apply the simpler computation for the distance-based desired gain (i.e., Equation 7). Signal (c) is the output of the distance-based automatic gain control for the cardioid (using Equation 7); signal (d) is the output of the distance-based automatic gain control for the omni (using Equation 7); signal (e) is the output of the distance-based automatic gain control with proximity-effect compensation for the cardioid (using Equations 7, 29, 32); and signal (f) is obtained from processing the omni signal with a conventional signal-based automatic gain control (Ableton Live 8) at a setting of 10 ms attack and 1s release time. Due to the proximity effect, the cardioid (a) shows a larger level increase at close distances than the omni (b). Since sound arrival was from the front, the maximum proximity effect occurred. After processing with the distance-based automatic gain control, the cardioid signal (c) still shows a level bias at close distances due to the bass boost of the proximity effect, whereas the omni signal (d) provides equal levels for all distances. If the cardioid signal is processed with both the distance-based automatic gain control and the proximity-effect compensation (e), the signal levels become uniform. As expected in plot (f), the omni signal processed by a conventional signal-based automatic gain control also provides equal levels, however on cost of distorted short-term dynamics.

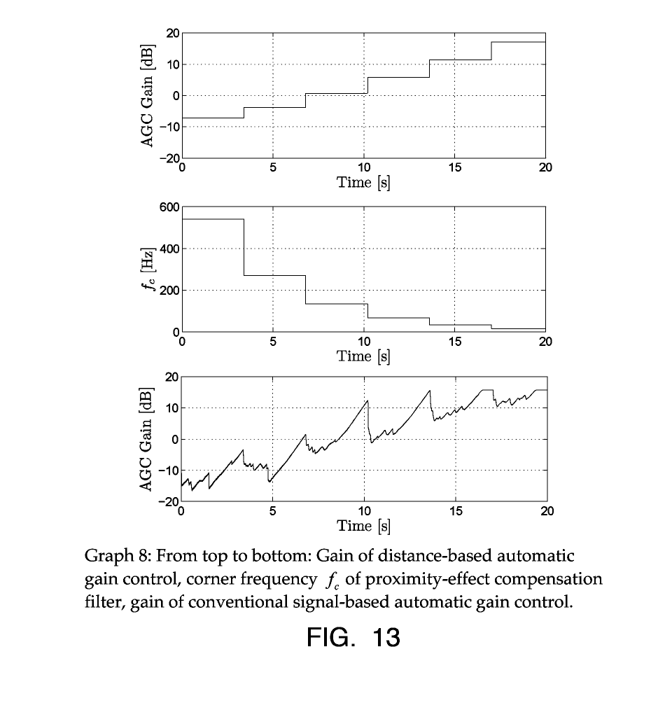

FIG. 13 shows Graph 8, which displays the inner workings of the algorithms that produced the results in Graph 7. The distance-based automatic gain control results in a step-wise gain, since for each distance the gain is at a fixed level, unlike the signal-based automatic gain control, where the gain constantly changes and reacts to individual speech syllables, even though the distance changes every 3.4 seconds. For the distance-based automatic gain control, Graph 8 also shows the corner frequency of the applied proximity-effect compensation filter. As expected, the corner frequency decreases as the distance increases. Informal listening tests confirmed that neither level-changes nor spectral changes (i.e., bass boost) are heard in the signals processed by the distance-based automatic gain control with proximity-effect compensation, unlike for the original microphones signals that are disturbing to listen to, due to the large level change of ˜20 dB (from 2.5 cm to 80 cm), and in the case of the directional microphone, due to the additional bass boost of >20 dB (at 100 Hz) for close talking distances (2.5 cm and 5 cm).

The processed signals shown in Graph 7 (c)-(e) confirmed that the theoretical results in apply well to recorded voice.

While various embodiments have been described, it will be appreciated by those of ordinary skill in the art that modifications can be made to the various embodiments without departing from the spirit and scope of the invention as a whole.

What is claimed is:

1. An automatic gain control system for use with a sound source and a microphone, comprising:
a gain controller configured to receive an input audio signal and configured to generate an output audio signal; wherein the gain controller is configured to control a level of the output audio signal based on a distance between the sound source and the microphone.

2. The system of claim 1, wherein the gain controller comprises a gain control module, which is configured to generate a gain control signal based on a desired gain for controlling the level of the output audio signal, the desired gain being determined based on a relationship between the sound pressure level at the microphone and the distance between the microphone and the sound source.

3. The system according to claim 2, wherein the gain controller further comprises a variable gain amplifier that is configured to receive the gain control signal generated by the gain control module and is further configured to control a gain of the variable gain amplifier based on the gain control signal.

4. The system according to claim 2, wherein the gain control module comprises a digital signal processor or an application specific integrated circuit that is adapted to perform computations to determine the desired gain for controlling the level of the output audio signal.

5. The system according to claim 1, further comprising a distance sensor adapted to determine the distance between the sound source and the microphone.

6. The system according to claim 1, wherein the distance between a sound source and a microphone accounts for a dimension of the sound source.

7. The system according to claim 2, wherein the relationship between the sound pressure level at the microphone and the distance between the microphone and the sound source is an inversely proportional relationship based on direct sound field model or a first order filter relationship based on a combined direct and diffuse sound field model.

8. A frequency control system for use with a sound source and a microphone, comprising:
a frequency response controller configured to receive an input audio signal and configured to generate an output audio signal; wherein the frequency response controller is configured to control the frequency spectrum of the output audio signal based on a distance between the sound source and the microphone.

9. The system according to claim 8, wherein the frequency response controller comprises a proximity-effect compensation module, which is configured to generate a filter control signal based on a desired frequency spectrum of the output audio signal determined based on the distance between the sound source and the microphone.

10. The system according to claim 9, wherein the filter control signal is also determined based on an angle of incidence of the sound with respect to the microphone.

11. The system according to claim 9, wherein the frequency response controller further comprises an adaptive filter that is configured to receive the filter control signal generated by the proximity-effect compensation module and is further configured to control a filter of the adaptive filter based on the filter control signal.

12. The system according to claim 9, wherein the proximity-effect compensation module comprises a digital signal processor or an application specific integrated circuit that is adapted to perform computations to determine the desired frequency spectrum of the output audio signal based on the distance between the sound source and the microphone and generate the filter control signal.

13. The system according to claim 8, further comprising a sensor adapted to determine the distance between the sound source and the microphone, and/or an orientation sensor adapted to determine the angle of incidence of the sound with respect to the microphone.

14. The system according to claim 8, wherein the distance between a sound source and a microphone accounts for a dimension of the sound source.

15. An audio signal processing system for use with a sound source and a microphone, comprising:
a frequency response controller configured to receive an input audio signal and configured to generate an output audio signal, wherein the frequency response controller is configured to control the frequency spectrum of the output audio signal based on a distance between the sound source and the microphone; and
a gain controller configured to control the level of the output audio signal based on the distance between the sound source and the microphone.

16. The system of claim 15, wherein the gain controller comprises a gain control module, which is configured to generate a gain control signal based on a desired gain for controlling the level of the output audio signal, the desired gain being determined based on a relationship between the sound pressure level at the microphone and the distance between the microphone and the sound source.

17. The system according to claim 16, wherein the gain controller further comprises a variable gain amplifier that is configured to receive the gain control signal generated by the gain control module and is further configured to control a gain of the variable gain amplifier based on the gain control signal.

18. The system according to claim 15, further comprising a distance sensor adapted to determine the distance between the sound source and the microphone.

19. The system according to claim 15, wherein the frequency response controller comprises a proximity-effect compensation module, which is configured to generate a filter control signal based on a desired frequency spectrum of the output audio signal determined based on a distance between the sound source and the microphone; and
an adaptive filter that is configured to receive the filter control signal generated by the proximity-effect compensation module and is further configured to control a filter of the adaptive filter based on the filter control signal.

20. The system according to claim 15, wherein the distance between the sound source and the microphone accounts for a dimension of the sound source.
